(19) United States
(12) Patent Application Publication
(10) Pub. No.: US 2011/0316563 A1
(43) Pub. Date: Dec. 29, 2011

(54) Capacitance Measurement Validation for Biomass Measurement Instruments

(76) Inventors: Stephen Jeffrey Davies, Wales (GB); Stephen Taylor, Wales (GB); Robert William Todd, Wales (GB); Lindsay Agate, Wales (GB); Matthew Lee, Wales (GB)

(21) Appl. No.: 13/132,432

(22) PCT Filed: Dec. 2, 2009
(86) PCT No.: PCT/GB2009/002813

§ 371 Date: Jul. 6, 2011

(30) Foreign Application Priority Data
Dec. 3, 2008 (GB) 0822058.4

(51) Int. Cl. G01R 27/26

(52) U.S. Cl. 324/663

(57) ABSTRACT

A system for validating capacitance measurement characteristics for a biomass measurement device (probe), is disclosed in which a test chamber for contains a test liquid medium, and a docking arrangement enables the measurement device to be disposed in the test medium in the chamber to measure the capacitance of the medium at a measurement zone in the chamber. A capacitive agent or structure (such as a capacitive device) is positioned in the test medium in the test chamber in a predetermined manner in order to provide a permittivity at the test zone which is different to the permittivity of the media without the capacitive agent or structure present.

### CROSS-REFERENCE TO RELATED APPLICATION

This application claims priority from PCT/GB/2009/002813 filed on Dec. 2, 2009 and from GB 0822058.4, filed Dec. 3, 2008, which is hereby incorporated by reference herein in its entirety.

### BACKGROUND OF THE INVENTION

1. Field of the Invention

The present invention relates to a method and system for validation of accuracy of capacitance measurement for a biomass measurement instrument.

2. State of the Art

In various industries and applications it is important to accurately measure the capacitance of a biomass dielectric medium. Such measurements are for example important in the brewing and pharmaceutical industries and in other sectors where commercially useful products are produced using living cells.

Systems and techniques which use capacitance measurement probes to measure capacitance of a biomass dielectric medium are disclosed in, for example, U.S. Pat. No. 6,496,020 and U.S. Pat. No. 4,810,650. Particularly in the pharmaceutical industry, it is important to be able to validate (i.e. to demonstrate accurate calibration of) measurement instrumentation such as measurement probes.

A typical known capacitance based biomass measuring probe is shown in FIG. 1 and FIG. 2. The probe 101 has a distal end which is inserted into the culture containing living cells (the biomass medium) and includes 2 pairs of platinum electrodes, which are formed as elongate strips at the distal end of the probe as shown most clearly in FIG. 2. The outer electrodes 2b are used to pass current through the biomass media. The inner electrodes 2a are used to sense the voltage across the gap between them. This arrangement is preferred over a simple 2 electrode arrangement in order to reduce the effect of polarisation that occurs at the current electrodes 2b. A radio frequency (RF) electric current is applied to the biomass solution via the current electrodes 2b, and the resultant voltage and current are sensed by the sensing electrodes 2a. Using the voltage and current measurements obtained, an appropriate processor is able to determine the capacitance (pF) and conductance (mS) of the solution. These values are then scaled using the known probe characteristics to give conductivity (mS/cm) and capacitance (pF/cm). Capacitance (pF/cm) is proportionally related to the permittivity of the solution.

The conductivity of the solution is typically related to the quantity of ions in the liquid which is also generally related to the amount of salts dissolved in the liquid. The current method of validating (testing and calibrating) a biomass measurement probe is by means of inserting the probe into a conductivity calibration solution and ensuring that the measurement channel is reading true through conductivity measurements. Standard conductivity calibration solutions are available which have a defined conductivity response linked to international standards such as NIST or NAMAS.

This method of conductivity calibration works successfully. It is more difficult to directly validate the accuracy of calibration of a probe in respect of a value of capacitance that is derived distinctly and independently of the conductivity measurement. This is particularly important in view of the fact that it is the capacitance part of the measurement that is used to give a measure of viable biomass.

To date, this has been difficult to achieve over different points in the working range of capacitance biomass measurements. This is because no solutions exist which have a defined capacitance other than that of water (approximately 7 pF/cm) in the relevant working range.

### SUMMARY OF THE INVENTION

An improved system and technique has now been devised. According to a first aspect, the present invention provides a system for validating capacitance measurement characteristics for a biomass measurement device, the system comprising:
a test chamber for containing a test liquid medium;
a docking arrangement for positioning the measurement device to be validated in the test medium in the chamber to measure the capacitance of the medium at a measurement zone in the chamber;
a capacitive agent or structure positionable in the test medium in the test chamber in a predetermined manner in order to provide a predetermined permittivity in the measurement zone which is different to the permittivity of the media without the capacitive agent present.

According to a second aspect, the invention provides a method of validating capacitance measurement characteristics for a biomass measurement device, the method comprising:
positioning a capacitance measurement device in a liquid test medium, the liquid test medium also including, disposed therein, a capacitive agent or structure in order to provide a predetermined permittivity change to the test medium;
operating the measuring device to deliver current to the test medium and enable resultant voltage and current to be determined;
processing the resultant voltage and current to provide a value for capacitance of the test medium;
comparing the capacitance value derived with an expected capacitance value.

The key to the invention is therefore ensuring that a capacitive agent or structure is repeatably positionable with respect to the measurement device, in order to ensure that the permittivity of a liquid test medium in a measurement zone is altered in a consistently repeatable fashion.

The effective permittivity of the test medium as measured by the measurement device is different when the capacitive agent or structure is present in the medium, and when it is not.

Beneficially a baseline or reference measurement is taken without the capacitive agent or structure acting as a capacitor (i.e. not having a capacitive effect).

Beneficially a test measurement is taken to compare with the baseline or reference. When taking the test measurement it is preferred that the capacitive agent or structure has a capacitive effect.

In one embodiment, the measurement device preferably comprises a probe having a measurement electrode arrangement. In such an embodiment the probe beneficially has an active electrode arrangement for passing a current into the liquid media. Beneficially the system provides for different alternating current frequencies to be passed into the liquid media.

The capacitive agent or structure may comprise a capacitive device. The capacitive device may comprise an electrode device having one or more capacitors arranged to be connected to electrodes positioned in the medium. The electrode device may be a passive electrode device which does not deliver current to the liquid media. The capacitive device in certain embodiments includes a circuit having a switch permitting either one or none of the capacitors to be connected across the electrodes.

The capacitive device may be removable from the system to enable monitoring measurement to be made without the capacitive device being present.

The capacitive device is preferably mounted at a predetermined position with respect to the measurement device. The chamber may be provided with a specific mounting arrangement for mounting the capacitive device.

In a preferred embodiment the capacitive device has spaced electrode plates, preferably the electrode plates being positioned on either side of the measurement probe or the axis of the measurement probe.

It is preferred that, in certain embodiments, the capacitive effect of the capacitive device can be varied in a predetermined manner in order to vary the change in permittivity at the test zone. Capacitors of different value and means for switching between the different value capacitors can enable this to be achieved.

In certain embodiments, it is preferred that the capacitive agent or structure can be removed from the chamber in order to permit measurement at the measurement zone without the capacitive agent present.

The liquid test medium may be a conductivity calibration solution. This enables the system to have additional functionality in being able to conduct a conductivity calibration validation procedure in addition to the capacitance calibration procedure.

### BRIEF DESCRIPTION OF THE DRAWINGS

The invention will now be described in specific embodiments, by way of example only, and with reference to the accompanying drawings.

FIGS. 1 and 2 are schematic side and underside views of a known capacitance measurement probe for use in biomass measurement applications;

FIG. 3 is a schematic view of a system in accordance with the invention;

FIGS. 4 and 5 are alternate perspective views of an alternative system in accordance with the present invention;

FIG. 6 is a schematic sectional view of the system of FIGS. 4 and 5 and

FIG. 7 is a diagrammatic representation of a circuit associated with the system of FIGS. 4 to 6.

### DETAILED DESCRIPTION OF THE PREFERRED EMBODIMENTS

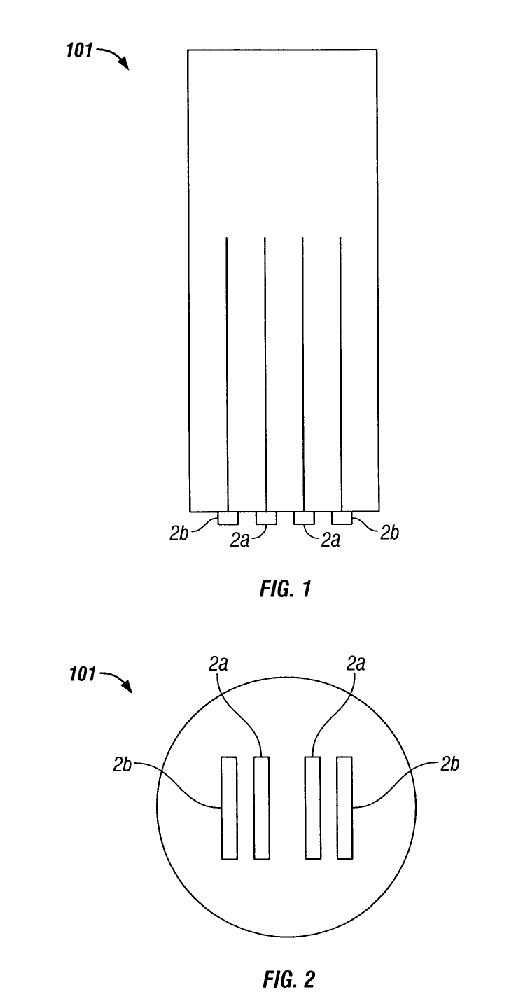

Referring to the drawings, the measurement probe 1 is generally in accordance with the measurement probe 101 of FIGS. 1 and 2. The (RF) electric current is applied via the current electrodes 2b, and the resultant voltage and current sensed by the sensing electrodes 2a. Using the voltage and current measurements obtained, an appropriate processor is able to determine the capacitance (pF) and conductance (mS) of the solution. This technique is known in the art and described in, for example U.S. Pat. No. 4,810,650.

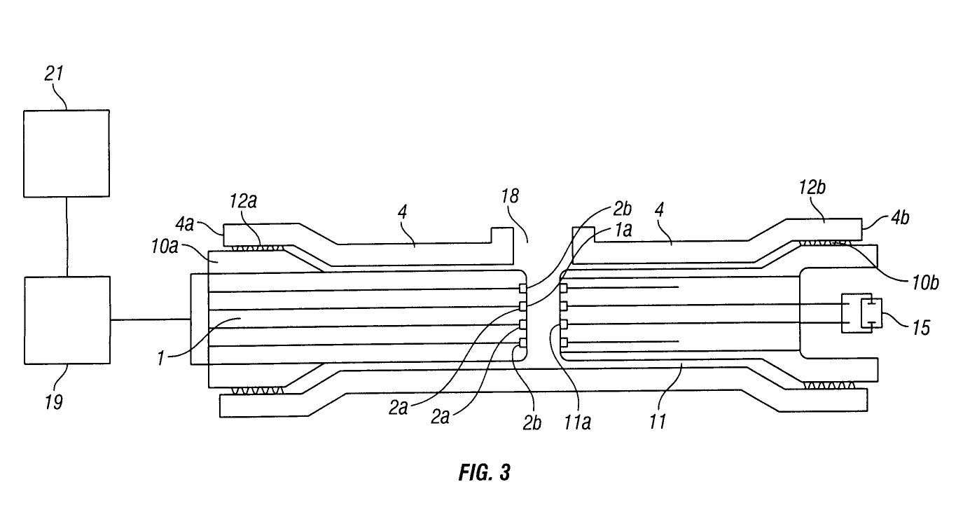

In order to calibrate the probe 1 with reference to validation of capacitance measurement, a test system as shown in FIG. 3 may be used. In the arrangement shown, the measurement probe is mounted into a chamber housing 4 by means of a distal threaded connection between a threaded circumference of the probe 10a and a threaded bore portion 12a of the housing. The probe enters the open end 4a of the chamber housing 4 and screws into the housing to a stop position. This ensures that the mounted probe distal end 1a is positioned at a predetermined position in the chamber housing 4. A second probe 11 is received within the chamber housing entering via the opposed end 4b of the chamber housing 4 and similarly is mounted into the chamber housing 4 by means of a distal threaded connection between a threaded circumference of the probe 10b and a threaded bore portion 12b of the housing. The probe enters the open end 4a of the chamber housing 4 and screws into the housing to a stop position. This ensures that the mounted probe distal end 11a is positioned at a predetermined position in the chamber housing 4.

The probe 11 is a passive probe in that current is not supplied by the outer electrodes 2b. The electrodes 2b are connected to a capacitor 15 and the purpose of the probe 11 is to alter the permittivity in a test zone that can be defined as existing in the chamber housing 4 in the zone between the probe ends 1a, 11a. Because of the capacitive effect of the presence of the probe 11 adjacent the end la of probe 1, the permittivity of the media in the test zone will be altered vis a vis the permittivity of the media that would otherwise exist. In this respect, it will be realised by those skilled in the art that there are potentially realisable embodiments of the invention in which the second probe 11 is replaced with an alternative capacitive agent that can have a similar effect to change the permittivity at the measurement zone. The essential feature in its broadest aspect is that a capacitive agent or structure is arranged in the test medium in the test chamber in a predetermined manner in order to provide a predetermined permittivity at the test zone which is different to the permittivity of the media without the capacitive agent present.

In an alternative embodiment that is realisable without undue effort, the copycat probe 11 could be conveniently replaced with a capacitive device having passive electrodes only (ie without the redundant electrodes 2a, 2b and with the electrode shape and dimensions and material optimised.

Furthermore the idea of putting a capacitive device in the measurement zone to affect the permittivity could be implemented by using alternative realisations of capacitive device. For example a device comprising layers of plastics and metals alternating, if placed at the test zone would have the desired effect. A structure having a plastics shell or membrane encasing a conductive centre, if positioned accurately would for example have the desired effect.

It is important that the spacing between the end of the measurement probe 1 and the capacitive agent or structure (probe 11) which defines the measurement zone, is kept at a consistent (accurately repeatable) distance. This is to ensure that when the probe 1 is mated with the housing 4 on subsequent occasions the validation procedure is truly repeated with the capacitive agent or structure (probe 11) being at the same spacing distance from the probe tip 1a. It is also beneficial for the spacing to be within a range of 3 mm to 15 mm, more preferably at about 5 mm.

In certain embodiments the capacitive agent or structure (probe 11) may be mounted in a recess in the chamber housing and access via an end to remove the capacitive agent or structure (probe 11) need not be provided via an end bore of the chamber housing.

Between the opposed ends of the chamber housing 4 is an entry port 18 through which liquid test media may be poured into the chamber housing 4 in order to completely immerse the end of the probe 1 and the capacitive agent or structure (probe 11). Conveniently the liquid test media used will be a known conductivity calibration solution such as proprietary conductivity calibration solutions available for example from Hanna Instruments Company. Such calibration solutions are water based and used for calibration/validation in relation to conductivity. The capacitance of such a solution is known to be about 7 pF/cm. When the chamber housing 4 is filled with the test solution, the capacitance reading that is achieved by the measurement device will vary from the expected result because of the presence of the capacitive agent or structure (probe 11). This variation will however be consistent and repeatable and therefore enable validation testing/calibration of probes. Typically validation will occur across a range of RF current frequencies. The various current and voltage outputs will be processed by the system processor 19 to be output on a display or other output means 21.

It is furthermore possible for the calibration/validation testing to be conducted at different effective permitivity values. This could be achieved for example by replacing different standard fitments or dimensioned capacitive agent or structures (probe 11). Or by enabling a capacitive agent or structure (probe 11) to be inserted to different defined points in the housing, or have different or variable capacitance values. The threaded connection 4b 10b between the chamber housing 4 and the probe 11 could be accurately driven under processor control to set the tip of the capacitive agent or structure (probe 11) at different spacing distances from the end of measurement probe 1.

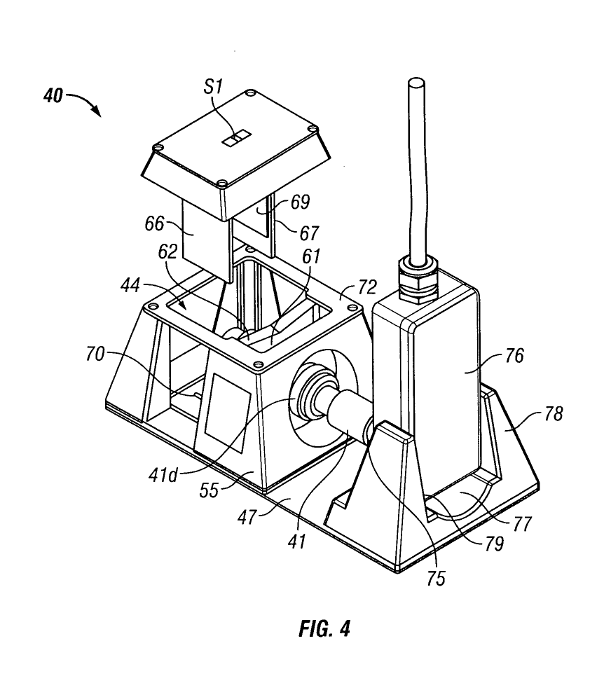

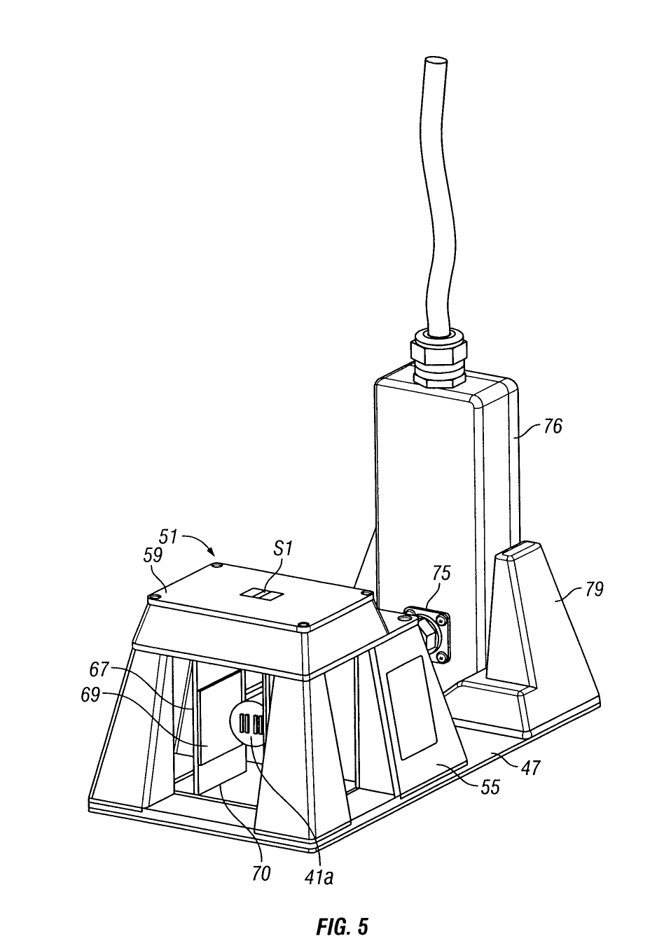

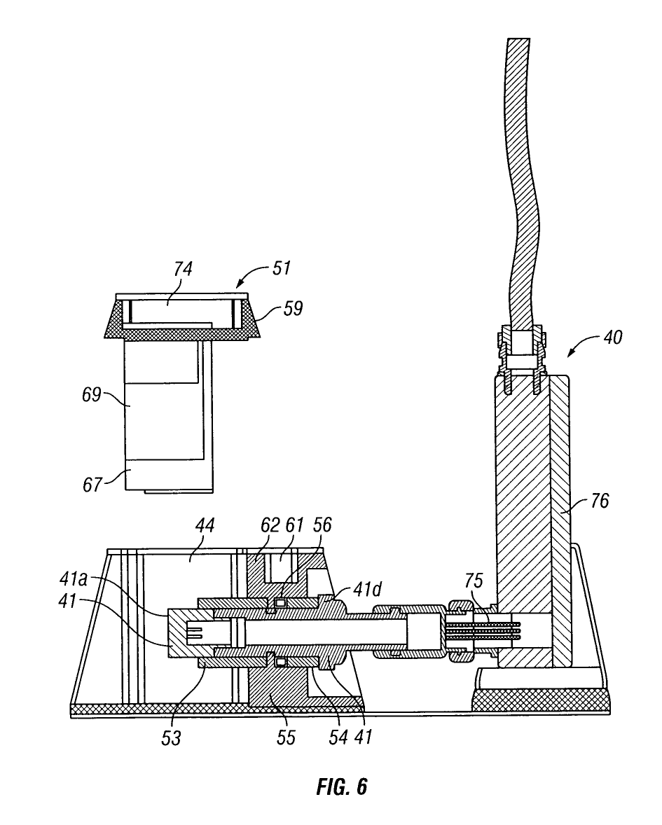

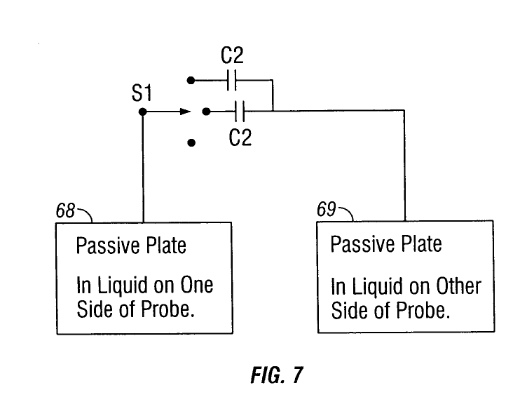

A second embodiment of validation system is shown in FIGS. 4 to 7. In the embodiment shown the test rig 40 is provided for receiving a probe 41. The test rig 40 has a base plate 47 to which is mounted a probe docking body 55. A probe 41 is mounted to be received in the docking body 55, such that the measurement end 41a of the probe is repeatably positioned at the same position within a test chamber 44 provided adjacent the docking body 55. The docking body 55 comprises a bore shaped and dimensioned to receive a first and second cylinders 53 54 arranged coaxially. The coaxial cylinders receive the length of the probe 41 in a repeatable and accurate manner. The probe 41 is provided with an annular shoulder 41d which abuts against the end of the cylinder 54 in order to ensure accurate and repeatable positioning of the probe 41. A seal 56 is provided between the end of cylinder 54 and an annular protrusion formed in the docking body 55 between the adjacent ends of the cylinders 53, 54.

The test chamber 44 has three transparent sidewalls enabling viewing of the interior of the chamber. The top of the chamber 44 is open, enabling the chamber to be filled with the relevant liquid test medium. An overflow reservoir 61 communicates with the chamber 44 by means of a channel extending over a weir structure 62. The top of the chamber 44 is closed by a cover portion 59 of a capacitive structure 51. The capacitive structure 51 comprises the cover portion 59 and a pair of spaced arms 66 67 each carrying a respective electrode plate 68 69. The capacitive structure 51 is also provided with a circuit as shown in FIG. 7enabling the electrode plates to be connected to neither or either one of capacitors C1 and C2. C1 is a high value capacitor. C2 is a low value capacitor. The switch Si enables selection between the capacitors. The capacitors C1 C2 and switch Si are typically housed in a void 74 provided internally of the cover portion 59 and the circuit includes the electrode plates 68 69. The capacitive structure is passive in that a current is not supplied. The electrode plates 68 69 can be connected to the capacitors C1 or C2 (or neither) and the purpose of the structure disposed in the test medium is to alter in a repeatable fashion the permittivity in the test zone adjacent the probe tip 41a (i.e. in the test medium in the chamber housing 4 adjacent the probe tip 41a). The two capacitors C1 and C2 enable different testing regimes to be applied.

When the arms 66 67 are inserted into the chamber 44, the lower edges of the arms are received in respective side slots 70. This ensures accurate and repeatable positioning of the arms in the chamber 44. The arms 66 67 are positioned one on either side of the probe tip 41. The underside of the cover portion 59 rests on a peripheral surface provided about the open upper part of the chamber 44 by an apertured support plate 72.

The output terminals of the probe 41 are, as known in prior art arrangements connected by an appropriate connector 75 to a head amplifier device 76. The head amplifier device provides an amplified signal to a monitoring device (such as a biomass monitor). The head amplifier device 76 is received to be resting in a seat 77 defined between upstanding sidewalls 78 79, and mounted to the base plate 47.

In a validation testing procedure using the system of the invention for validating a biomass measurement probe, the probe 41 is connected to a biomass monitor and positioned in the correct docking position in the test rig 40, as shown in the figures. A fixed volume of standard conductivity solution is introduced into the chamber 44 and a measurement of conductivity is recorded. This measurement is taken without the capacitive structure 51 present. The conductivity measurement can be compared to the known conductivity of the solution in order to validate calibration for conductivity measurement.

The capacitive structure 51 is then introduced and placed in position such that the arms 66 67 are positioned one on either side of the probe tip 41 and the underside of the cover portion 59 rests on the peripheral surface about the open upper part of the chamber 44. In doing this the test solution will overflow the weir structure into the overflow reservoir. With the switch Si in the off position such that neither capacitor C1 or C2 is connected across the electrodes 68 69, the monitor measures the capacitance. In this configuration a base line measure of capacitance is measured by the monitor.

Next the switch Si is operated to connect either capacitor C1 or C2 across the electrodes. The capacitance value is measured using the monitor and compared with the expected value. The expected value is known for each of C1 and C2 from laboratory calibration and testing.

The invention provides a convenient system and technique for direct validation of a capacitance measurement instrument for use in biomass measurement applications. The system additionally enables a conductivity validation/calibration to be made.

1. A system for validating capacitance measurement characteristics for a biomass measurement device, the system comprising:
a test chamber for containing a test liquid medium;
a docking arrangement for positioning the measurement device to be disposed in the test medium in the chamber to measure the capacitance of the medium at a measurement zone in the chamber;
a capacitive agent or structure for disposal in the test medium in the test chamber in a predetermined manner in order to provide a permittivity at the test zone which is different to the permittivity of the media without the capacitive agent or structure present.

2. A system according to claim 1, wherein the measurement device comprises a probe having measurement electrodes.

3. A system according to claim 1, wherein the capacitive agent or structure comprises a capacitive device.

4. A system according to claim 3, wherein the capacitive device comprises an electrode device having one or more capacitors which may be connected across electrodes positioned in the medium.

5. A system according to claim 3, wherein the capacitive device is mounted at a predetermined position with respect to the measurement device.

6. A system according to claim 3, wherein the capacitive effect of the capacitive device can be varied in a predetermined manner in order to vary the change in permitivity permittivity at the test zone.

7. A system according to claim 1, wherein the capacitive agent or structure can be removed from the chamber in order to permit measurement at the test zone without the capacitive agent or structure present.

8. A system according to claim 1 including means for delivering alternating current to the test medium at a range of different frequencies.

9. A system according to claim 1, wherein the chamber is provided with means for positioning the capacitive agent or structure at a predetermined distance spaced from an opposed measuring electrode arrangement of the measurement device.

10. A system according to claim 1 wherein the liquid test medium is conductivity calibration solution.

11. A system according to claim 1 which is also enabled to conduct a conductivity calibration validation procedure.

12. A method of validating capacitance measurement characteristics for a biomass measurement device, the method comprising:
positioning a capacitance measurement device in a liquid test medium, the liquid test medium also including, disposed therein, a capacitive agent or structure in order to impart an effective permittivity change to the test medium;
operating the measuring device to deliver current to the test medium and enable resultant voltage and current to be determined;
processing the resultant voltage and current to provide a value for capacitance of the test medium;
comparing the capacitance value derived with an expected capacitance value.

13. A method according to claim 12, wherein a baseline or reference measurement is taken without the capacitive agent or structure acting as a capacitor.

14. A method according to claim 13, wherein a test measurement is taken to compare with the baseline or reference.

15. A method according to claim 14, wherein, when taking the test measurement the capacitive agent or structure has a capacitive effect.
